(19) United States
(12) Patent Application Publication
(10) Pub. No.: US 2016/0258908 A1
(43) Pub. Date: Sep. 8, 2016

(54) METHOD FOR EVALUATING ATOMIC VACANCY IN SURFACE LAYER OF SILICON WAFER AND APPARATUS FOR EVALUATING THE SAME

(71) Applicant: NIIGATA UNIVERSITY, Niigata-shi, Niigata (JP)

(72) Inventors: Terutaka GOTO, Niigata-shi (JP); Yuichi NEMOTO, Niigata-shi (JP); Hiroshi KANETA, Niigata-shi (JP); Mitsuhiro AKATSU, Niigata-shi (JP); Keisuke MITSUMOTO, Niigata-shi (JP)

(73) Assignee: NIIGATA UNIVERSITY, Niigata-shi, Niigata (JP)

(21) Appl. No.: 15/031,187

(22) PCT Filed: Nov. 5, 2014
(86) PCT No.: PCT/JP2014/005580

§ 371 Date: Apr. 21, 2016

(30) Foreign Application Priority Data
Nov. 8, 2013 (JP) 2013-232352

(51) Int. Cl. G01N 29/24; G01N 29/44; H01L 21/66

(52) U.S. Cl. CPC G01N 29/2462; H01L 22/12; G01N 29/2437; G01N 29/44; H01L 29/34

(57) ABSTRACT

A method for evaluating atomic vacancies in a silicon wafer surface layer includes: element formation in which a pair of comb-shaped electrodes are formed on the same surface of a silicon sample over piezoelectric thin films; detection during which the sample is cooled and an ultrasonic pulse generated from one electrode while an external magnetic field is applied, the ultrasonic pulse being propagated through the sample surface and received by the other electrode, and a phase difference being detected between the ultrasonic pulse generated by the one electrode and the ultrasonic pulse received by the other electrode; and evaluation during which the sample surface elastic constant is determined on the basis of the phase difference, and the atomic vacancies in the sample surface are evaluated on the basis of changes in the elastic constant according to temperature or changes in the elastic constant according to the magnetic field intensity.

### TECHNICAL FIELD

The present invention relates to a method for evaluating atomic vacancy in the surface layer of a silicon wafer and an apparatus for evaluating the same.

### BACKGROUND OF THE RELATED ART

Recently, semiconductor elements (LSI: large Scale Integration) typified by DRAMs and flash memories are being multi-functionalized and upgraded with the development of telecommunication equipment, etc., while the demand for the semiconductor device is remarkably increased by the diffusion of cellular phone, portable music player, smart phone, etc. Correspondingly, the demand for silicon wafers as the material constituting the semiconductor elements is also remarkably increased and the efficient manufacturing technique for manufacturing silicon wafers with high quality is required so as to comply with the future increase of demand for the semiconductor wafers.

By the way, in semiconductor industry, the silicon wafers generally are manufactured by means of Czochralski method (CZ method) or float zone method (FZ method). Each of the silicon wafers manufactured by the aforementioned method contains lattice defects to some degrees. The lattice defects are mainly classified into atomic vacancy which is formed by the lacking of one of the silicon atoms from the regular lattice positions and point defect which is formed by the entering of the silicon atom in irregular sites of the silicon lattice. Particularly, if the atomic vacancies are conjugated to form voids as secondary defect, the electric properties and the manufacturing yield of the device manufactured by the use of the silicon wafers are surely affected. For the processing of the high-end device such as telecommunication equipment, therefore, annealed silicon wafers treated by a prescribed process, epitaxial wafer, perfect crystalline silicon wafers in which the growth of the void as the secondary defect is suppressed are employed.

The annealed silicon wafer is obtained by annealing for the silicon wafer so as to remove the surface void. Moreover, the epitaxial silicon wafer is obtained by forming the epitaxial layer, of which the impurity concentration and thickness are severely controlled, on the silicon wafer. Namely, since the annealed silicon wafer and the epitaxial silicon wafer require secondary processing for the silicon wafer cut of the silicon ingot, the manufacturing steps are increased so that the intended silicon wafer has difficulty in efficient manufacturing process. With regard to the annealed silicon wafer and the epitaxial silicon wafer, furthermore, the aforementioned secondary processing cannot be conducted for a silicon wafer of large diameter (commercially available 300 mm-diameter wafer and developing 450 mm-diameter wafer).

Recently, therefore, the perfect crystalline silicon wafer, in which the growth of the void is suppressed and only the atomic vacancy and interstitial atom are left, is practically employed. Even in the perfect crystalline silicon wafer, however, the atomic vacancy-rich area and the interstitial atom-rich area are required to be defined so as to improve the electric properties and the manufacturing yield of the intended device.

In this point of view, in the development of the growth technique of the high quality CZ silicon crystalline ingot, the measuring method in quantity of the atomic vacancy concentration by the ultrasonic measurement is required. It is expected that the property in manufacturing process of the device using the perfect crystalline silicon wafer which is obtained by slicing the CZ silicon crystalline ingot can be controlled by evaluating the existence vacancy concentration of the perfect crystalline silicon wafer in advance with the ultrasonic measurement, thereby contributing the improvement of the manufacturing yield of the intended silicon wafer.

One of the inventors has proposed an atomic vacancy analyzing apparatus using the ultrasonic measurement (Patent document 1). In the atomic vacancy analyzing apparatus, an external magnetic field is applied to and passed through a silicon sample under cooling condition and the intended atomic vacancy concentration is evaluated from the conspicuous decline of the curve showing the relation between the change in ultrasonic velocity and the cooling temperature.

By the way, since the surface layer with a thickness of 1 to 3 μm of the silicon wafer is used in the device fabrication, the semiconductor industry intensely demands the measurement of the atomic vacancy of the surface layer of the silicon wafer. However, the evaluating technique of the atomic vacancy locating only in the surface layer of the silicon wafer being distinguished from the atomic vacancy of the interior of the silicon wafer has not been known.

Patent document 1: Japanese Patent Application Laid-open H07-174742

### DISCLOSURE OF THE INVENTION

### Problem to be Solved by the Invention

In this point of view, it is an object of the present invention to provide a new method for evaluating the atomic vacancy in the surface layer of the silicon wafer and a new apparatus for evaluating the same.

### Technical Solution

The present invention relates to a method for evaluating atomic vacancy in a surface layer of a silicon wafer, including the steps of: forming a pair of surface acoustic wave (SAW) devices which are arranged opposite to one another on the same main surface of a silicon wafer; generating a ultrasonic wave pulse from one of the surface acoustic wave (SAW) devices and propagating the ultrasonic wave pulse in a surface layer of the silicon sample while the silicon sample is cooled under a condition of an application of magnetic field, and receiving the propagated ultrasonic wave pulse at the other of the surface acoustic wave (SAW) devices, thereby measuring a difference in phase between the generated ultrasonic wave pulse and the propagated ultrasonic wave pulse; and calculating an elastic constant Cₛ of the surface layer of the silicon sample based on the difference in phase and evaluating a concentration “N” of atomic vacancy in the surface layer of the silicon sample based on a change of the elastic constant Cₛ with a temperature or a change of the elastic constant Cₛ with an intensity of the magnetic field.

The silicon sample is cooled within a temperature range of 10 mK to 20 K.

The intensity of the magnetic field is set within a range of 0 to 10 teslas.

Each of the surface acoustic wave (SAW) devices includes a piezoelectric film formed on the main surface of the silicon wafer and a comb-shaped electrode formed on the piezoelectric film.

The piezoelectric film is made of zinc oxide, aluminum nitride or polyvinylidene fluoride and the comb-shaped electrode is made of aluminum (Al) or copper (Cu).

The silicon sample is attached to a silver plate or a silver film.

The concentration “N” of atomic vacancy is defined by obtaining a low temperature softening ΔCₛ/Cₛ of the elastic constant Cs of the surface layer of the silicon sample and considering that the softening of the elastic constant Cₛ of the surface acoustic wave (SAW) corresponds to the concentration of atomic vacancy of N=(1.6±0.2)×10¹²/cm³ as the use of unit of ΔCₛ/Cₛ=10⁻⁴.

The concentration “N” of atomic vacancy is defined by obtaining a low temperature softening ΔCₛ/Cₛ dependent on a change of the intensity of the magnetic field within a range of 0 to 10 teslas when the elastic constant Cs of the surface layer of the silicon sample is calculated at a temperature within a range 10 mK to 50 mK and considering that the softening of the elastic constant Cₛ of the surface acoustic wave (SAW) corresponds to the concentration of atomic vacancy of N=(1.6±0.2)×10¹²/cm³ as the use of unit of ΔCₛ/Cₛ=10⁻⁴.

The present invention also relates to an apparatus for evaluating atomic vacancy in a surface layer of a silicon wafer, including: a silicon sample provided with an ultrasonic wave oscillating portion and an ultrasonic wave receiving portion; a magnetic field generator for applying an external magnetic field to the silicon sample; a refrigerator for cooling the silicon sample; and a measuring means for measuring a difference in phase between an ultrasonic wave pulse injected from the ultrasonic wave generating portion and an ultrasonic wave pulse propagated in the silicon sample and received at the ultrasonic wave receiving portion; wherein the ultrasonic oscillating portion and the ultrasonic receiving portion are respective comb-shaped electrodes formed on corresponding piezoelectric films and are formed on the same main surface of the silicon sample.

The piezoelectric film is made of zinc oxide, aluminum nitride or polyvinylidene fluoride and the comb-shaped electrode is made of aluminum (Al) or cupper (Cu).

The silicon sample is attached to a silver plate or a silver film.

Moreover, the present invention relates to a silicon wafer, including a concentration of atomic vacancy in a surface layer thereof which is evaluated by one of the aforementioned evaluating methods and distinguished from a concentration of atomic vacancy in a bulk thereof.

Furthermore, the present invention relates to a method for manufacturing a silicon wafer, including steps of: forming a pair of surface acoustic wave (SAW) devices which are arranged opposite to one another on the same main surface of a silicon sample; generating an ultrasonic wave pulse from one of the surface acoustic wave (SAW) devices and propagating the ultrasonic wave pulse in a surface layer of the silicon sample while the silicon sample is cooled under a condition of an application of magnetic field, and receiving the propagated ultrasonic wave pulse at the other of the surface acoustic wave (SAW) devices, thereby measuring a difference in phase between the generated ultrasonic wave pulse and the propagated ultrasonic wave pulse; and calculating an elastic constant Cₛ of the surface layer of the silicon sample based on the difference in phase and evaluating a concentration “N” of atomic vacancy of the surface layer of the silicon sample based on a change of the elastic constant Cₛ with a temperature or a change of the elastic constant Cₛ with an intensity of the magnetic field.

In addition, the present invention relates to a silicon wafer manufactured by the aforementioned manufacturing method.

### Effect of the Invention

According to the method and apparatus for evaluating atomic vacancy in a surface layer of a silicon wafer can be evaluated a concentration of atomic vacancy in the surface layer of a silicon wafer which is distinguished from the interior of the silicon wafer.

### BRIEF DESCRIPTION OF THE DRAWINGS

FIG. 1 is a schematic view showing a portion for cooling a silicon sample according to an embodiment of an apparatus for evaluating atomic vacancy in a surface layer of a silicon wafer of the present invention.

FIG. 2 is a photograph showing a sample holder wherein the silicon sample is set.

FIG. 3 is a perspective view schematically showing the structure of the silicon sample.

FIG. 4 is a photograph showing the silicon sample.

FIG. 5 is a block diagram showing the constitution of the evaluating apparatus.

FIG. 6 is a graph showing the temperature dependence of the elastic constant Cₛ of the surface acoustic wave (SAW) propagating in the surface layer of a boron-doped CZ wafer.

FIG. 7 is a graph showing the temperature dependence of the elastic constant Cₛ of the surface acoustic wave (SAW) propagating in the surface layer of a boron-doped CZ wafer under the application of magnetic fields.

FIG. 8 is a graph showing the magnetic field dependence of the elastic constant Cₛ of the surface acoustic wave (SAW) propagating in the surface layer of a boron-doped CZ wafer at low temperatures.

FIG. 9 is a theoretically analytic graph showing the temperature dependence of the elastic constant Cₛ of the surface acoustic wave (SAW) propagating in the surface layer of a boron-doped CZ wafer under the applied magnetic fields relating to FIG. 7.

FIG. 10 is a theoretically analytic graph showing the magnetic field dependence of the elastic constant Cₛ of the surface acoustic wave (SAW) propagating in the surface layer of a boron-doped CZ wafer at low temperatures relating to FIG. 8.

FIG. 11 is a chart showing the displacement vectors where the surface acoustic wave (SAW) propagates along the direction of [100] on the surface of a silicon wafer with the orientation of (001).

FIG. 12A is a graph showing the oscillation amplitude of the symmetry elastic strains of ε_{B}, ε_{U}, ε_{V}, ε_{ZX} consisting of the displacement vectors Uₓ, U_{z} to be excited by the surface acoustic wave (SAW), wherein the elastic strains of ε_{B}, ε_{zx} and the elastic strains of ε_{U}, ε_{V} propagate along the X-direction with being oscillating in reverse phase.

FIG. 12B is a graph showing the amplitude of the elastic strains ε_{B}, ε_{U}, ε_{V}, ε_{ZX} of the surface acoustic wave (SAW) in penetrating into the z-direction of the silicon wafer with being oscillating in reverse phase.

FIG. 13A is a graph showing the oscillation energies U_{B}, Uᵤ, Uᵥ, U_{zx} relating to the symmetry strains ε_{B}, ε_{U}, ε_{V}, ε_{ZX} associated with the surface acoustic wave (SAW) propagating along the X-direction, wherein the energy of the surface acoustic wave (SAW) propagating along the X-direction is composed of the portion Uₜₒₜₐₗ oscillating and propagating with time and the portion not oscillating with time.

FIG. 13B is a graph showing the oscillation energies U_{B}, Uᵤ, Uᵥ, U_{ZX} relating to the symmetry strains ε_{B}, ε_{U}, εᵥ, ε_{ZX} associated with the surface acoustic wave (SAW) in penetrating into the z-direction of the silicon wafer and shows the total energy Uₜₒₜₐₗ in penetrating into the silicon wafer.

FIG. 14 is an explanatory view showing the quantum state of atomic vacancy orbital as the base for the theoretically analysis (FIGS. 9 and 10) to be employed to determine the atomic vacancy concentration from the temperature change of the elastic constant Cs of the surface acoustic wave (SAW) (FIG. 6) and the magnetic field dependence of the surface acoustic wave (SAW) (FIGS. 7 and 8).

FIG. 15 shows the temperature dependence and the magnetic field dependence of the quadrupole susceptibility to be employed in the theoretical analysis (FIGS. 9 and 10).

FIG. 16 is an explanatory view showing the electric quadrupoles Ou, Ov, Ozx conjugating to the symmetry strains ε_{U}, ε_{V}, ε_{ZX} induced by the surface acoustic wave (SAW) and the elastic constants employed in the analysis by the quadrupole susceptibility of the atomic vacancy orbital.

### MODE FOR CARRYING OUT THE INVENTION

Hereinafter, embodiments of the present invention will be described with reference to drawings.

### Example 1

### Apparatus for Evaluating Atomic Vacancy in Surface Layer of Silicon Wafer

The structure of the apparatus for evaluating the atomic vacancy in the surface layer of a silicon wafer according to the present embodiment will be described.

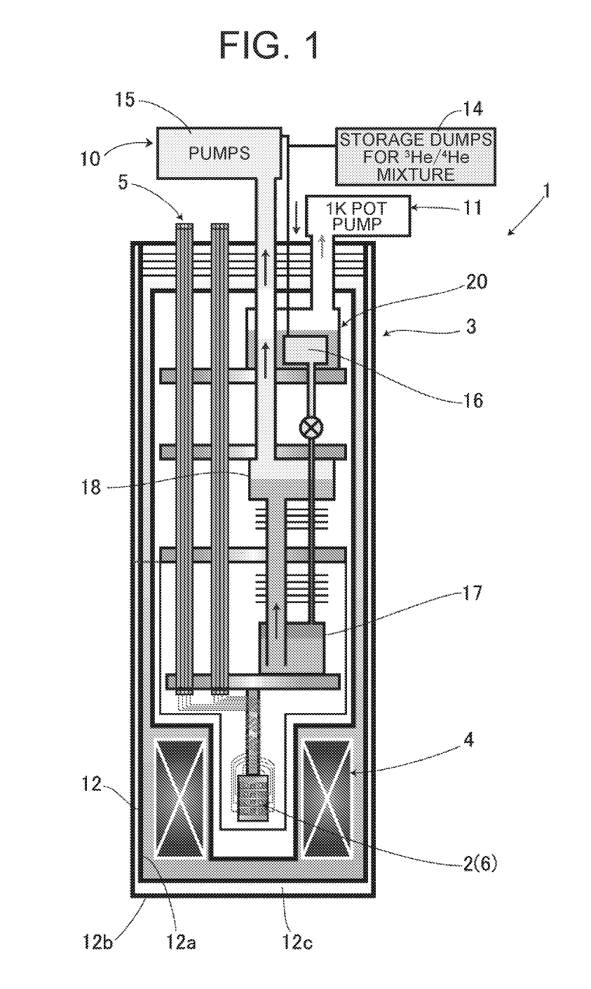

In FIG. 1 showing the apparatus for evaluating the atomic vacancy in the surface layer of the silicon wafer, the apparatus 1 is provided with a sample holder 2, a dilution refrigerator 3 as a cooling means, a magnetic field generator 4 and coaxial lines 5. As a whole, the apparatus 1 is configured such that the silicon sample 6 set in the sample holder 2 is cooled to a prescribed temperature under the application of an external magnetic fields and the acoustic velocity of the ultrasonic wave pulse propagated in the surface layer of the silicon sample 6 is evaluated.

The magnetic field generator 4 is provided around the position where the silicon sample 6 is set so as to apply the external magnetic field to the silicon sample 6. As the magnetic field generator 4 can be exemplified a superconducting magnet. Since the acoustic velocity of the ultrasonic wave pulse propagated in the surface layer of the silicon sample 6 is evaluated, if needed, under the application of the external magnetic field to the silicon sample 6, the magnetic field generator 4 is configured such that the intensity of the external magnetic field is controlled at least within a range of 0 to 10 teslas.

The dilution refrigerator 3 is configured such that the silicon sample 6 set in the sample holder 2 is cooled and controlled at least within a range of 20 mK to 20 K. In this embodiment, the dilution refrigerator 3 is constituted of two systems of ³He—⁴He gas mixture system 10 and ⁴He system 11, allowing the interior of the dewar 12 to be cooled to a prescribed temperature. The dewar 12 has the double structure made of the inner layer 12a and the outer layer 12b so as to form the vacuum space 12c between the inner layer 12a and the outer layer 12b.

The ³He—⁴He gas mixture system 10 is configured to have cooling performance enough as the dilution refrigerator 3. The ³He—⁴He gas mixture system 10 is provided with a storage tank 14, a circulating pump 15, a condenser 16, a mixing chamber 17 and a still 18. The circulating pump 15 is different from a normal pump 15 and configured such that ³He gas is not leaked outside therefrom. The condenser 16 is configured to cool the ³He gas pumped via the circulating pump 15 to the ³He liquid, which flows down into the mixing chamber 17 consisting of the phase-separated liquid states of the ³He dense phase floating over the ³He dilute phase.

The mixing chamber 17 is the lowest portion in temperature in the dilute refrigerator 3. The interface of the phase-separated ³He—⁴He mixture liquid phases exists in the mixer 17. The upper half of the mixing chamber 17 is occupied by the ³He dense phase which is continuously supplied from the condenser 16. The lower half of the mixing chamber 17 is occupied by the ³He dilute phase (the concentration of the ³He: about 3%, the balance: superfluid ⁴He) and connected with the still 18. In the mixing chamber 17, the ³He atom is forcibly transferred into the dilute phase with almost no entropy from the dense phase with large entropy, so that the cooling performance of the dilute refrigerator 3 is caused by the difference in entropy.

The still 18 are configured to electively evaporate only the ³He gas in the dilute phase. The still 18 are kept at a prescribed temperature (e.g., 0.8K). As a result, the ³He-gas possesses a predominant vapor pressure at 0.8 K in contrast to a tiny vapor pressure of ⁴He gas at the same temperature.

The ⁴He system 11 is configured to liquefy the ³He gas. The ⁴He system 11 has a 1 k pot 20 with an evacuating pump. In the ⁴He system 11, the pumping of the ⁴He-gas in the 1 K pot 20 by the evacuating pump causes the intended cooling performance. In this embodiment, the continuous operation can be conducted by introducing the ⁴He liquid directly from the dewar 12 via the condenser 16 and the ³He gas is liquefied at the condenser 16.

In FIG. 1, the sample holder 2 where the silicon sample 6 is set thermally anchored to the mixing chamber 17. In this embodiment, moreover, the mixing chamber 17 is made of a material with large thermal conductivity so as to indirectly cool the silicon sample 6 down to 10 mK by using the thermal conduction from the material of the mixing chamber 17. In this case, the cooling temperature range can be advantageously enlarged to the side of high temperature of up to 20 K.

The coaxial lines 5 is configured to inject an ultrasonic wave pulse into the surface of the silicon wafer and to receive the ultrasonic wave pulse propagated in the surface layer of the silicon wafer 6, thereby to measure the sonic velocity of the ultrasonic wave pulse propagated therein.

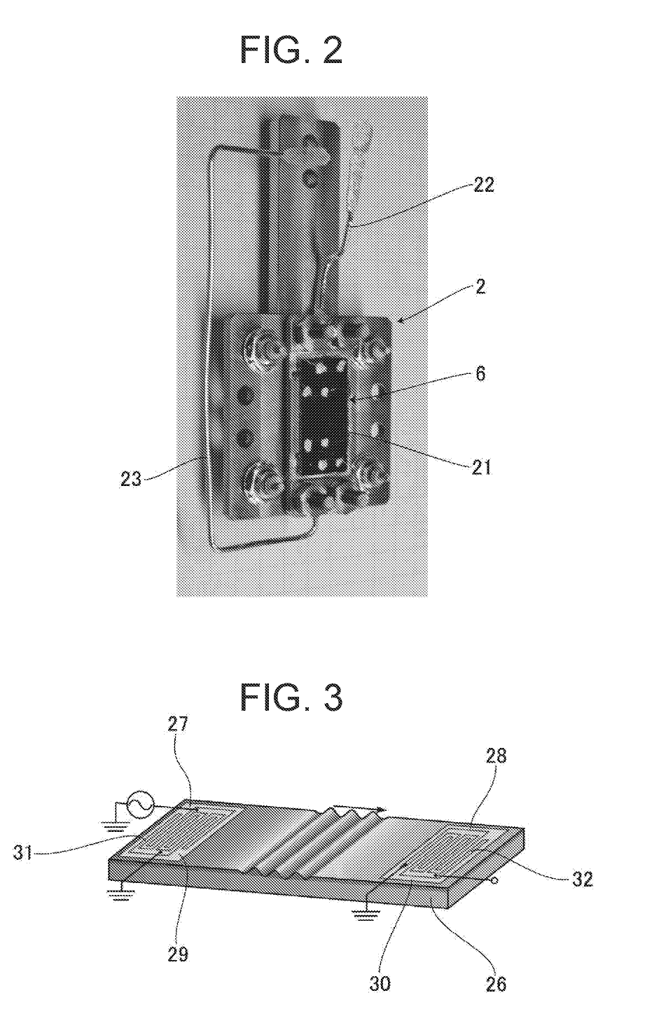

As shown in FIG. 2, the silicon sample 6 is held on the sample holder 2 through the attachment to the silver plate 21 made pure silver. Here, the silver plate 21 cools the silicon sample 6 through the contacting of the silicon sample 6 with the silver plate 21 so as not to be affected by the temperature change if an external magnetic field is applied. Moreover, the silver wires 22 and 23 are provided for cooling the silicon sample 6.

As shown in FIG. 3, moreover, the silicon sample 6 is provided with a silicon wafer 26, an ultrasonic wave generating portion 27 provided on a main surface of the silicon wafer 26 as the surface acoustic wave (SAW) devices, and an ultrasonic wave receiving portion 28. The ultrasonic wave generating portion 27 and the ultrasonic receiving portion 28 are formed on the same main surface of the silicon wafer, and piezoelectric films 29, 30 and comb-shaped electrodes 31, 32, which are formed on the piezoelectric films, are provided. The electrodes 31 and 32 are configured to apply an electric field to the surface layer of the silicon wafer. The piezoelectric films 29, 30 and the comb-shaped electrodes 31, 32 constitute a transducer. In this embodiment, the piezoelectric films 29 and 30 are made of ZnO films with a thickness of 2 μm. The comb-shaped electrodes 31 and 32 are made of Al or Cu with electrically grounded at one port and configured as a comb shape by setting corresponding wires in parallel. The piezoelectric film 29 and 30 are made by means of sputtering and the comb-shaped electrodes 31 and 32 are made by means of photolithography. The thickness of each of the comp-shaped electrodes 31 and 32 is set to 1 μm or less and the width “W” of each of the wires of the comb-shaped electrodes 31 and 32 is set to 2.5 μm. Moreover, the pitch of the wires of the comb-shaped electrodes 31 and 32 is set to 2.5 μm equal to the width “W” of the wire. The width “W” is set one-fourth of the wavelength of the ultrasonic wave pulse to be injected from the ultrasonic generating portion 27. Then, the comb-shaped electrodes 31 and 32 are configured such that the wires of the electrodes 31 and 32 are arranged in parallel as shown in FIG. 3 while the electrode 31 is provided opposite to the electrode 32.

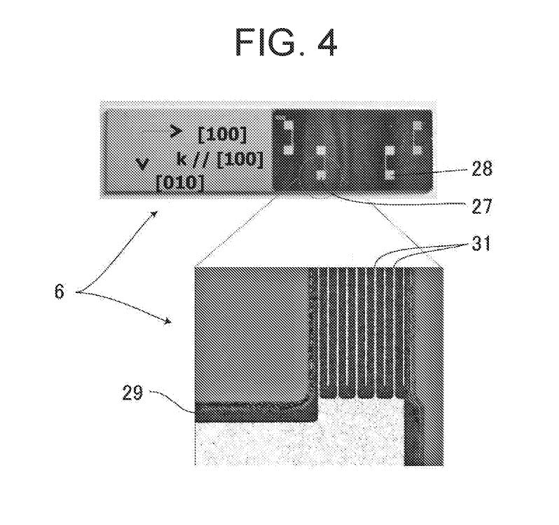

FIG. 4 shows a practical silicon sample 6. In the partially enlarged view shown in the lower side, the black portion corresponds to a piezoelectric film 29 and the white portion corresponds to a comb-shaped electrode 31 made of Al which is formed on the piezoelectric film 29. The piezoelectric film 29 is formed by means of sputtering and the comb-shaped electrode 31 is formed by means of photolithography. The silicon sample 6 is formed in a rectangle shape with a length of 40 mm, a width of 10 mm and a thickness of 0.776 mm.

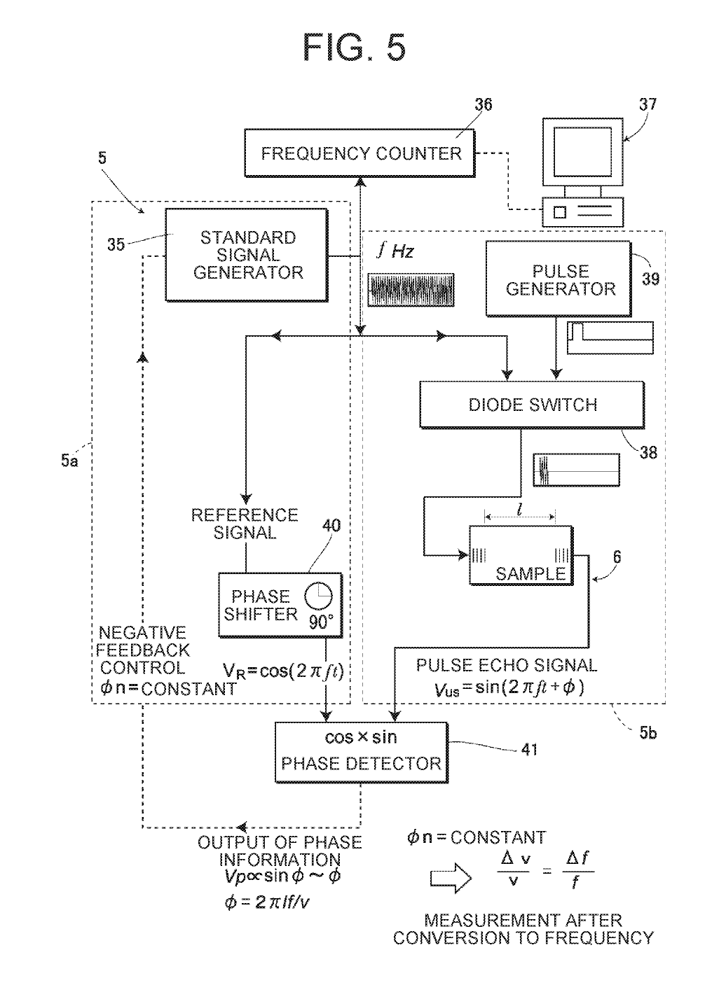

Then, the structure and the function of the coaxial lines 5 will be described referring to FIG. 5. The coaxial lines 5 is configured to measure the difference in phase between a reference signal obtained by the direct measurement of the fundamental signal of the ultrasonic wave pulse to be applied to the silicon sample 6 and a measurement signal of the surface acoustic wave (SAW) pulse propagated in the surface layer of the silicon sample 6. In this embodiment, the coaxial lines 5 are provided with a standard signal generator 35, a frequency counter 36, a personal computer 37, a diode switch 38, a pulse generator 39, a phase shifter 40 and a phase detector 41.

The standard signal generator 35 is configured to generate a standard sinusoidal signal, which is divided into a reference signal 5a and a measurement signal 5b. The frequency counter 36 is configured to measure the standard signal and output the measurement signal to the personal computer 37.

The reference signal 5a is transferred to the phase detector 41 via the phase sifter 40. On the other hand, the measurement signal 5b is transferred to the phase detector 41 via the diode switch 38 with which the pulse generator 39 is connected and the silicon sample 6, the diode switch 38 and the silicon sample 6 being subsequently arranged. The diode switch 38 is configured to divide the standard sinusoidal signal into a plurality of signals, each having a prescribed width.

The phase detector 41 is configured to compare the reference signal based on the standard signal and the measurement signal output from the silicon sample 6 and to measure the sonic velocity of the ultrasonic wave pulse in the silicon wafer 26.

It is preferable the coaxial lines 5 are configured to have a zero detecting means which changes an oscillating frequency so as to maintain the difference in phase constant by the change of temperature and magnetic field. It is also preferable the coaxial lines 5 are configured to simultaneously measure a plurality of points of a plurality of silicon sample 6 or a single silicon sample 6.

### [Method for Evaluating Atomic Vacancy in Surface Layer of Silicon Wafer]

The method for evaluating the atomic vacancy in the surface layer of a silicon wafer according to the present embodiment will be described.

First of all, the silicon sample 6 configured such that the ultrasonic wave generating portion 27 and the ultrasonic wave receiving portion 28 are formed on the main surface of the silicon wafer 26 which is made by cutting a prescribed portion of the silicon ingot is cooled at a temperature within a range of 20 K or below, as needed, under the condition of the application of an external magnetic field.

Then, the standard sinusoidal signal is generated by the standard signal generator 35. The standard signal is divided into the reference signal 5a and the measurement signal 5b. The standard signal of the measurement signal 5b is divided into a plurality of signals, each having a width of, e.g., 0.5 μs, at the diode switch 38.

The corresponding alternating electric field is applied to the comb-shaped electrodes 31 and 32 by the signals divided at the diode switch 38. Due to the alternating electric field, the piezoelectric film 29 is polarized to cause the corresponding elastic strain so that the ultrasonic wave generating portion 27 generates an ultrasonic wave pulse based on the divided signals. In this manner, the divided signals are converted into the corresponding mechanical signal, that is, the corresponding ultrasonic wave pulse.

The ultrasonic wave pulse propagates in the surface layer of the silicon wafer 26 within a range from the main surface of the silicon wafer 26 to the depth of wavelength λ of 10 μm or less. The ultrasonic wave pulse propagated in the surface layer of the silicon wafer 26 is received at the ultrasonic wave receiving portion 28 and then converted into the corresponding electric signal to be output

The thus obtained measurement signal and the reference signal are compared at the phase detector 41 to measure the difference φ in phase between the ultrasonic wave referenced pulse and the thus obtained measurement ultrasonic wave pulse. The sound velocity v is calculated from the equation (1): φ=2πlf/v by using the difference φ in phase. Here, symbol “l” designates the propagation length of the surface acoustic wave and the symbol “f” designates the frequency of the ultrasonic wave. As a result, the sonic velocity is calculated as 4.967 km/sec, which is well matched to the calculated value of 4.844 km/sec of Rayleigh wave predicted from the theoretical calculation of the surface acoustic wave (SAW).

The elastic constant Cₛ is calculated from the equation (2): Cₛ=ρv² by using the calculated sound velocity. Here, ρ means a density of silicon and has a value of 2.33 g/cm³.

In this manner, the sound velocity “v” is evaluated from the difference φ in phase of the ultrasonic wave pulse. Then, the elastic constant Cₛ is calculated from the sound velocity “v” while the cooling temperature is decreased, and the kind and concentration of the atomic vacancy existing in the silicon wafer 26 can be evaluated from the decrease amount of the elastic constant Cₛ. Alternatively, the elastic constant Cₛ is calculated from the sound velocity “v” while the magnetic field is decreased under the condition of constant temperature, and the kind and concentration of the atomic vacancy existing in the silicon wafer 26 can be evaluated from the decrease amount of the elastic constant Cₛ. It is because the decrease amount of the elastic constant Cₛ is proportion to the concentration of the atomic vacancy.

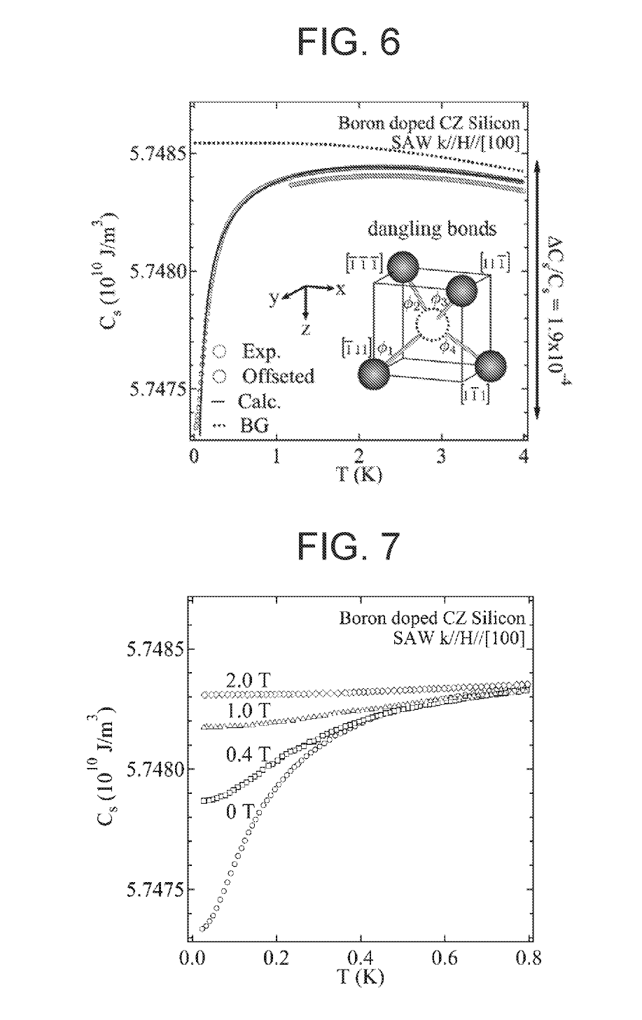

If the silicon sample 6 is made from a boron-doped CZ wafer and the change in elastic constant Cₛ with the cooling temperature is evaluated when the silicon sample 6 is cooled down to 4K and below, for example, the graph shown in FIG. 6 can be obtained. Here, the frequency of the ultrasonic wave pulse is 523 MHz, the propagation direction is parallel to the crystal orientation of [100], the distance “d” between the comb-shaped electrodes 31, 32 is 15 mm, and the intensity of the magnetic field is zero. The graph exhibits that the elastic constant Cₛ is remarkably decreased proportion to the reciprocal number of temperature, that is, low temperature softening. In this case of FIG. 6, the extrinsic phase shift due to the superconducting transition of Al used for the comb-shaped electrodes 31, 32 is superposed on the change of the elastic constant.

The atomic vacancy orbital around the atomic vacancy site with an enlarged radius of up to 1 nm or more has a large electric quadrupole and strongly coupled with ultrasonic wave strain. Moreover, the ground state becomes conspicuous in low temperature softening when the temperature approaches absolute zero where orbital degeneracy is caused. Furthermore, since three electrons are stored into the atomic vacancy orbital, the silicon sample 6 carries magnetic property. In this manner, the state of the atomic vacancy can be examined by using the quantum state of the atomic vacancy orbital.

Hereinafter, the relation between the amount of low temperature softening ΔCₛ/Cₛ of the elastic constant Cₛ of the surface layer of the silicon sample and the corresponding concentration of atomic vacancy will be described, based on the corresponding theoretical equations.

In this embodiment, the surface ultrasonic acoustic wave (SAW) to be propagated in the direction of [100] in the surface layer of the silicon sample with (001) orientation is employed. In this case, the longitudinal wave component Uₓ and the transverse wave component U_{z} travel in a state of elliptical orbital motion, as shown in FIG. 11. The low temperature softening of the elastic constant Cₛ of the surface acoustic wave (SAW) is caused by the interaction between the strain induced by the surface acoustic wave (SAW) and the electric quadrupole of the atomic vacancy orbital.

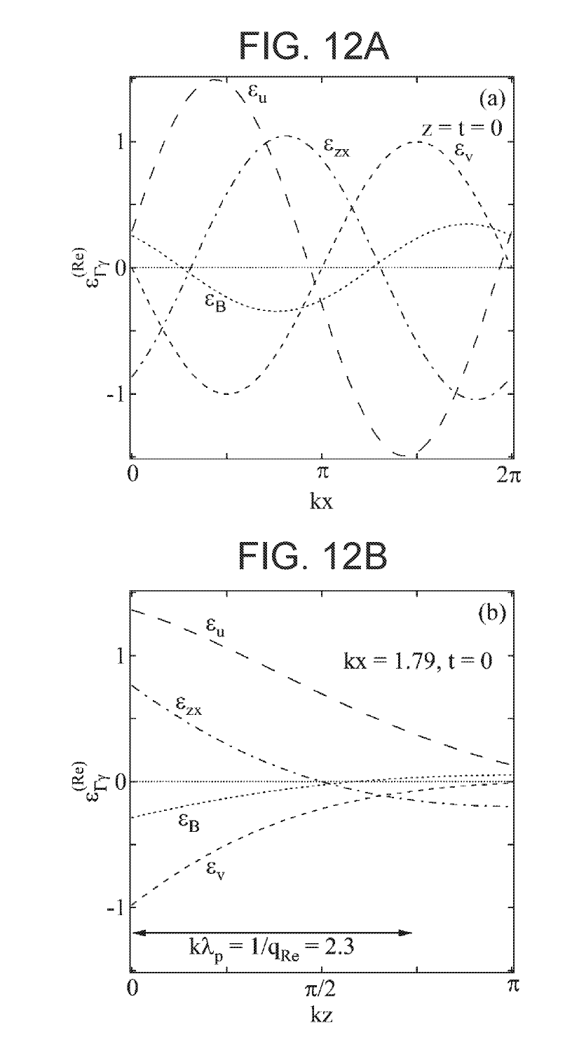

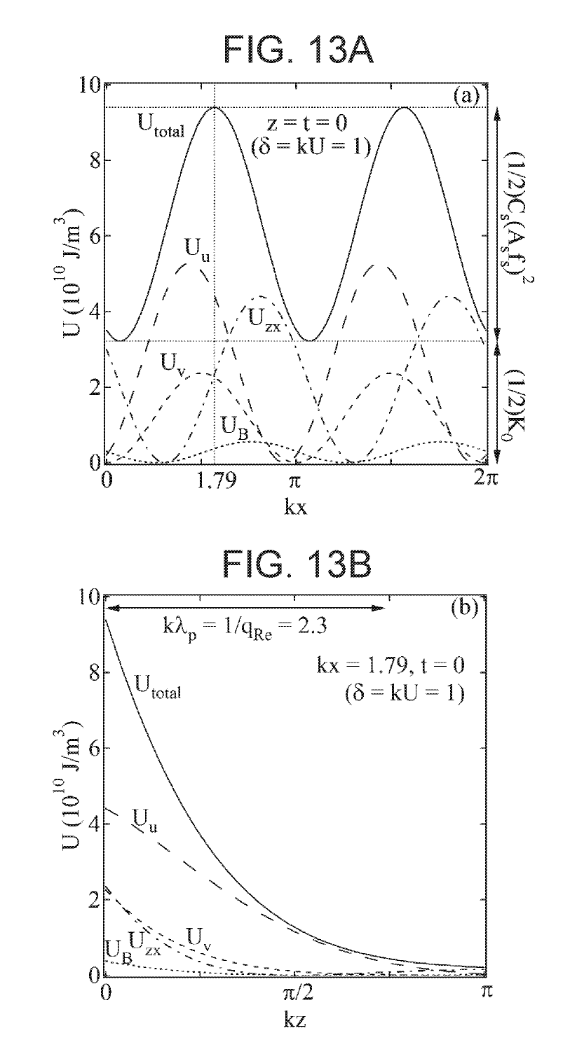

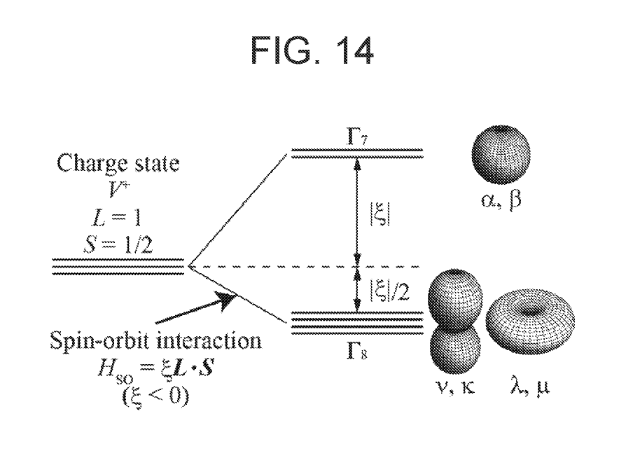

The symmetry strains ε_{B}, ε_{U}, εᵥ, ε_{ZX} contained the displacement vectors Uₓ, U_{z} to be excited by the surface acoustic wave (SAW) which is depicted in FIGS. 12A and 12B can be represented by the following equation (1):

ε_{B}=A_{B}kUexp[−kq_{Re}z] cos [k(x−vt)−kqₗₘz+θ_{B}]

εᵤ=AᵢkUexp[−kq_{Re}z] cos [k(x−vt)−kqₗₘz+θ_{B}]

εᵥ=AᵥkUexp[−kq_{Re}z] cos [k(x−vt)−kqₗₘz+θ_{B}]

ε_{zx}=A_{zx}kUexp[−kq_{Re}z] cos [k(x−vt)−kqₗₘz+θ_{B}] (1)

The parameter “q” relating to the attenuation with penetrating into the Z-direction of the surface acoustic wave can be represented by the following equation (2):

q=q_{Re}+iqₗₘ=0.4311−0.5216i (2)

The parameter relating to the amplitude “A” and the phase “θ” can be represented by the following equation (3):

A_{B}=0.346 (θ_{B}=42.61°)

Aᵤ=1.491 (θᵤ=281.37°)

Aᵥ=1.000 (θᵥ=90.00°)

A_{zx}=1.045 (θ_{zx}=214.41°) (3)

The interaction between the symmetry elastic strain induced by the surface acoustic wave (SAW) and the electric quadrupole can be represented by the following equation (4):

$${H}_{QS} = - {\sum }_{Γγ} {g}_{r} {O}_{Γγ} {A}_{Γγ} f ( z , x , t \text{:} {θ}_{Γγ} ) δ = - {g}_{Γ 3} {O}_{u} {A}_{u} f ( z , x , t \text{:} {θ}_{u} ) δ - {g}_{Γ 3} {O}_{v} {A}_{v} f ( z , x , t \text{:} {θ}_{v} ) δ - {g}_{Γ 5} {O}_{zx} {A}_{zx} f ( z , x , t \text{:} {θ}_{zx} ) δ \qquad ( 4 )$$

The function meaning the state of the oscillation with propagating along the X-direction and the attenuation with penetrating into the Z-direction can be represented by the following equation (5)

f_{Γ}_{_{y}}(x,z,t;θ_{Γ}_{_{y}}=exp[−kq_{Rc}z] cos [k(x−vt)−kqₗₘz+θ_{Γ}_{_{y}}] (5)

Moreover, the parameter “δ” proportion to the amplitude “U” of the surface acoustic wave (SAW) to be injected can be represented by the following equation (6):

δ=kU=2πU/λ (6)

Here, the symbol “k” means the wave number of the surface acoustic wave (SAW).

The free energy of the coupling system between the silicon lattice and vacancy orbital is calculated up to the second order of the external perturbation “δ” by using the perturbation Hamiltonian (equation (4)). By the twice differential calculus of the external perturbation “δ”, moreover, the low temperature softening of the elastic constant Cₛ (FIG. 5), the temperature dependence under magnetic field of the elastic constant Cₛ (FIG. 6) and the magnetic field dependence of the elastic constant Cₛ (FIG. 7) at low temperatures can be theoretically analyzed.

Then, a prescribed analysis will be performed using the following equation (7).

$${C}_{S} = {C}_{S}^{0} - \frac{N}{{( {A}_{s} {f}_{s} ( z , x , t \text{:} {θ}_{s} ) )}^{2}} [ {g}_{Γ 3}^{2} χ ( {O}_{u} ) {( {A}_{u} {f}_{u} ( z , x , t ; {θ}_{u} ) )}^{2} + {g}_{Γ 3}^{2} χ ( {O}_{v} ) {( {A}_{v} {f}_{v} ( z , x , t ; {θ}_{v} ) )}^{2} + {g}_{Γ 5}^{2} χ ( {O}_{zx} ) {( {Z}_{zx} {f}_{zx} ( z , x , t ; {θ}_{zx} ) )}^{2} ] \qquad ( 7 )$$

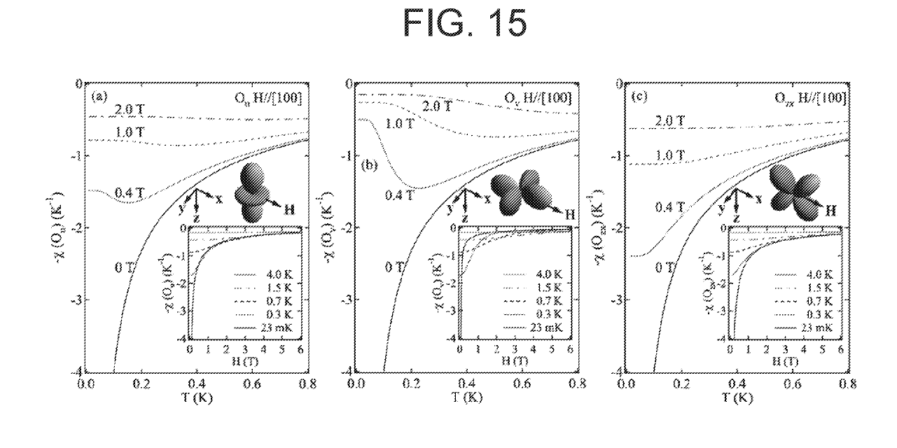

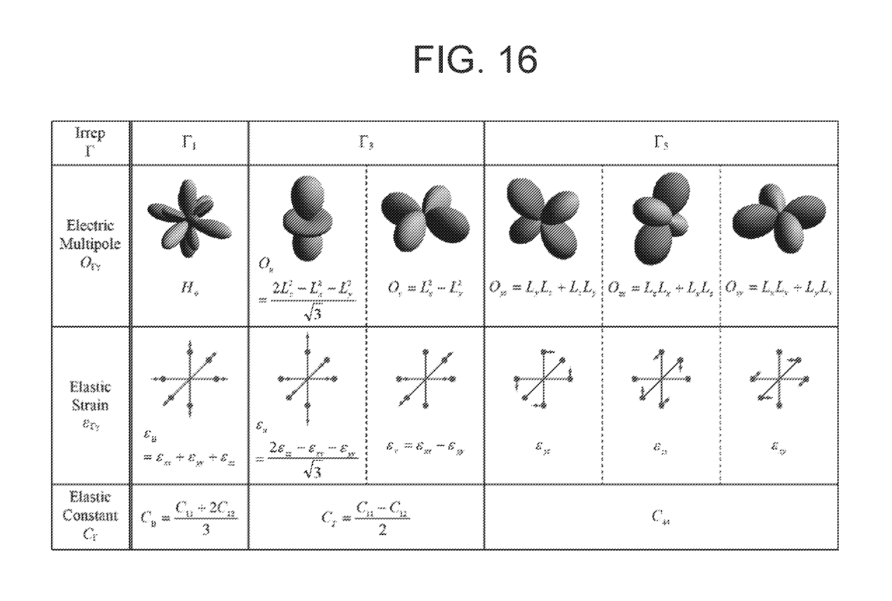

The aforementioned temperature dependence and magnetic field dependence of the elastic constant Cₛ is obtained by using the temperature and magnetic field dependence of the quadrupole susceptibility χ(Oᵤ), χ(Oᵥ) and χ(O_{zx}) shown in FIG. 15. In this case, the quadrupole-strain coupling constants g_{Γ5},g_{Γ3}, which are conceived by the present inventors, are employed as follows (Strong Quadrupole-Strain Interaction of Vacancy Orbital in Boron-Doped Czochralski Silicon: Kazuki Okabe, Mitsuhiro Akatsu, Shotaro Baba, Keisuke Mitsumoto, Yuichi Nnemoto, Hiroshi Yamada-Kaneta, Terutaka Goto, Hiroyuki Saito, Kazuhiko Kashima, and Yoshihiko Saito, Journal of Physical Society of Japan, Vol. 82, No. 12, Article ID 124604, Nov. 13, 2013):

g_{Γ}_{₅}=2.80×10⁵ K

g_{Γ}_{₃}=1.80×10⁵ K

The background Cₛ⁰ in the equation (1) can be represented by the following equation and changed slowly with temperature:

$${C}_{S}^{0} = {C}^{0} - \frac{s}{exp ( t \text{/} T ) - 1}$$

Here, “t”, “s” and “C⁰” can be represented by the following values:

t=7.3 K, s=6.3×10⁶ J/m³, C⁰=5.75×10¹⁰ J/m³

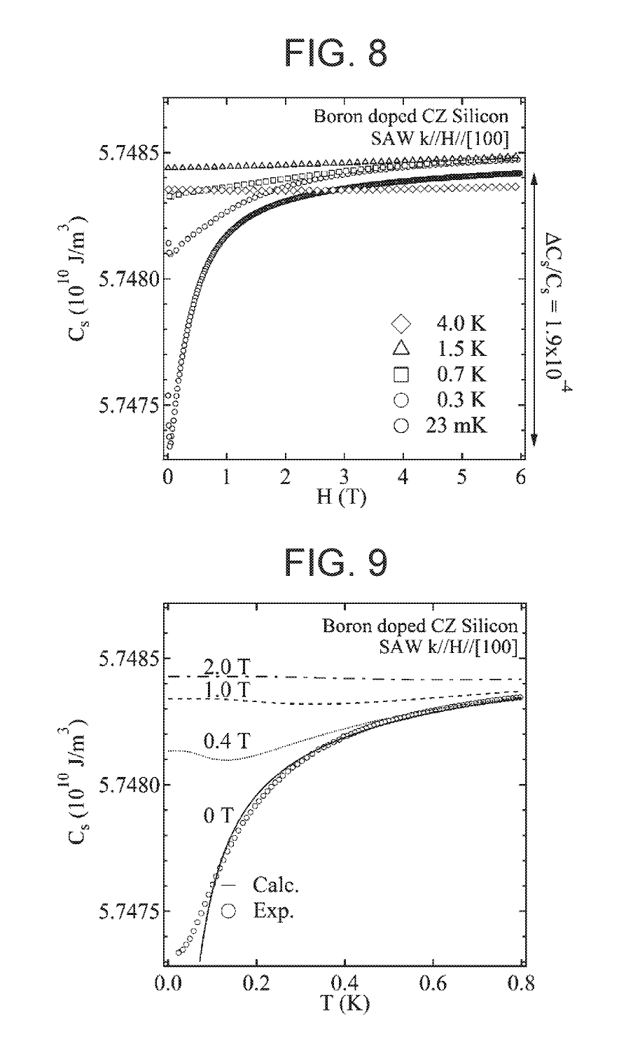

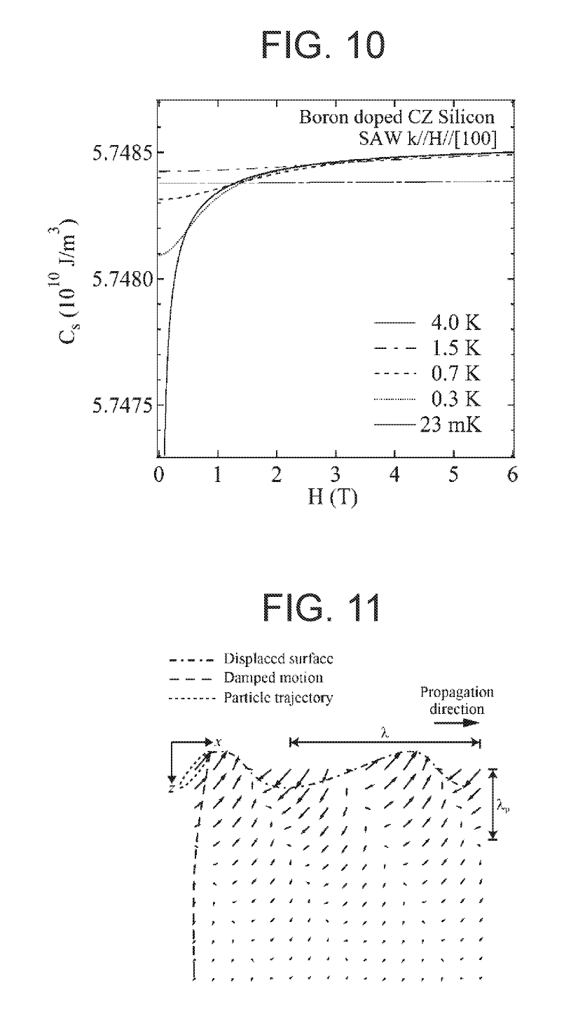

FIGS. 9 and 10 show the results of the theoretical calculation using the equation (7), and reproduce the experimental results relating to FIGS. 7 and 8. In this manner, the concentration of atomic vacancy existing in the surface layer of the silicon wafer (depth λ_{P}=about 3 μm) used in this embodiment is proportion to the value of 1.9×10⁻⁴ of the low temperature softening ΔCs/Cs and then calculated as N=3.1×10¹²/cm³, which means that the softening of the elastic constant Cₛ of the surface acoustic wave corresponds to the concentration of atomic vacancy of N=(1.6±0.2)×10¹²/cm³ as the use of unit of ΔCs/Cs=10⁻⁴. Here, the error contained in the coupling constant is considered. Therefore, the method for evaluating the concentration of atomic vacancy is established.

The low temperature softening of the surface acoustic wave (SAW) is diminished by the application of the external magnetic field. The diminishing configuration depends on the direction of the application of the magnetic field. The diminishing configuration becomes different dependent on the application of the magnetic field parallel to the propagating direction of the surface acoustic wave (SAW), the application of the magnetic field perpendicular to the propagating direction of the surface acoustic wave (SAW) and parallel to the main surface of the silicon wafer and the application of the magnetic field perpendicular to the main surface of the silicon wafer. The concentration of atomic vacancy can be evaluated in the surface layer of the silicon wafer from the magnetic field dependence of the low temperature softening.

FIG. 7 shows the magnetic field dependence of the elastic constant Cₛ in the surface layer of the boron-doped CZ wafer and FIG. 8 shows the temperature dependence of the boron-doped CZ silicon wafer under the application of the magnetic field. Here, the frequency of the ultrasonic wave pulse is 523 MHz, the propagating direction is parallel to the direction of the crystal orientation of [100], and the direction of the application of the magnetic field is parallel to the crystal orientation of [100]. The distance between the comb-shaped electrodes 31 and 32 is 7.5 mm. In FIG. 8, the temperature is set to 4 K, 1.5 K, 700 mK, 300 mK and 23 mK. In FIG. 7, the temperature is set to 0 T, 0.4 T, 1 T and 2 T. It is confirmed that the recovering amount of the low temperature softening due to the magnetic field corresponds to the amount of the low temperature softening under the application of magnetic field.

In this manner, the evaluating method of atomic vacancy in the surface layer of the silicon wafer includes the steps of; forming a pair of surface acoustic wave (SAW) devices which are arranged opposite to one another by forming the comb-shaped electrodes 31, 32 on the same main surface of the silicon sample 6 via the piezoelectric films 29, 30; generating an ultrasonic wave pulse from one 31 of the surface acoustic wave devices and propagating the ultrasonic wave pulse in the surface layer of the silicon sample while the silicon sample 6 is cooled under a condition of an application of magnetic field, and receiving the propagated ultrasonic wave pulse at the other 32 of the surface acoustic wave (SAW) devices, thereby measuring a difference in phase between the injected ultrasonic wave pulse and the propagated ultrasonic wave pulse; and calculating an elastic constant Cₛ of the surface layer of the silicon sample 6 based on the difference in phase and evaluating a concentration “N” of atomic vacancy of the surface layer of the silicon sample based on a change of the elastic constant Cₛ with a temperature or a change of the elastic constant Cₛ with an intensity of the magnetic field.

Preferably, the silicon sample 6 is cooled within a temperature range of 10 mK to 20 K.

Preferably, the piezoelectric films 29, 30 are made of ZnO and the comb-shaped electrodes 31, 32 are made of Al or Cu.

Preferably, the silicon sample is attached to the silver plate 21.

In this embodiment, the evaluating apparatus 1 includes: the silicon sample 6 provided with the ultrasonic wave from the generating portion 27 and the ultrasonic wave to the receiving portion 28; the magnetic field generator 4 for applying an external magnetic field to the silicon sample 4; the refrigerator 3 for cooling the silicon sample 6; and the measuring coaxial line 5 for measuring the difference in phase between the ultrasonic wave pulse injected from the ultrasonic wave generating portion 27 and the ultrasonic wave pulse propagated in the silicon sample 6 and received at the ultrasonic wave receiving portion 28; wherein the ultrasonic from the generating portion 27 and the ultrasonic receiving portion 28 are respective comb-shaped electrodes 31, 32 formed on corresponding piezoelectric films 29, 30 and are formed on the same main surface of the silicon sample 6.

In the method and apparatus for evaluating atomic vacancy in a surface layer of a silicon wafer according to this embodiment, the concentration of atomic vacancy in the surface layer with a thickness of 10 μm or less can be evaluated while distinguished from the concentration of the interior of the silicon wafer.

According to the present invention, technical breakthrough in semiconductor development process where test wafers for evaluating some properties thereof are made and evaluated can be promised. The neutral wafer, anneal wafer and epitaxial wafer which are employed in semiconductor industry are sold in the condition that electric resistivity representing concentration of boron, concentration of oxygen and concentration of COP representing void are indicated. In the present invention, moreover, the silicon wafers can be practically employed in the condition that the concentration of atomic vacancy measured by the ultrasonic wave is indicated. The atomic vacancy in the silicon wafer is a main factor predominating the precipitation of micro defect of oxide (BMD) in semiconductor manufacturing process. Therefore, if the concentration of atomic vacancy is practically indicated to silicon wafers, the manufacturing yield of forefront device such as memory, logic element (CPU) and image sensor can be remarkably enhanced and the high performance of power semiconductor gathering attention can be enhanced.

In this embodiment, the silicon sample 6 is attached to the silver plate 6, but may be attached to a silver film.

The present invention is not limited to the aforementioned embodiment, and may be varied and changed. In the evaluation of the concentration of atomic vacancy, the intensity of the magnetic field can be varied within a range of 0 to 10 teslas. Moreover, the piezoelectric films 29, 30 may be made of aluminum nitride (AlN) or polyvinylidene fluoride (PVDF) instead to zinc oxide (ZnO).

Furthermore, the concentration of atomic vacancy in the surface layer with a thickness of 3.5 μm to 0.18 μm may be selectively evaluated by setting the resonant frequency of the surface acoustic wave element within a range of 0.5 GHz to 10 GHz. In addition, the ultrasonic wave generating portion and the ultrasonic wave receiving portion may be configured to employ an ultrasonic wave pulse with a pulse width of 0.1 ρs to 1 μs.

### EXPLANATION OF SYMBOLS

1: apparatus for evaluating atomic vacancy
3: dilution refrigerator
4: magnetic field generator (superconducting magnetic
coil)
5: measuring coaxial line
6: silicon sample
21: silver plate
27: ultrasonic wave generating portion
28: ultrasonic wave receiving portion
29, 30: piezoelectric film
31, 32: comb-shaped electrode

1. A method for evaluating atomic vacancy in a surface layer of a silicon wafer, comprising the steps of:
forming a pair of surface acoustic wave (SAW) devices which are arranged opposite to one another on the same main surface of a silicon sample;
generating an ultrasonic wave pulse by one of the surface acoustic wave (SAW) devices and propagating the ultrasonic wave in a surface layer of the silicon sample while the silicon sample is cooled under a condition of an application of magnetic field, and receiving the propagated ultrasonic wave pulse at the other of the surface acoustic wave (SAW) devices, thereby measuring a difference in phase between the injected ultrasonic wave pulse and the propagated ultrasonic wave pulse; and
calculating an elastic constant Cₛ of the surface layer of the silicon sample based on the difference in phase and evaluating a concentration “N” of atomic vacancy of the surface layer of the silicon sample based on a change of the elastic constant Cₛ with a temperature or a change of the elastic constant Cₛ with an intensity of the magnetic field.

2. The evaluating method as set forth in claim 1,
wherein the silicon sample is cooled within a temperature range of 10 mK to 20 K.

3. The evaluating method as set forth in claim 1,
wherein an intensity of the magnetic field is set within a range of 0 to 10 teslas.

4. The evaluating method as set forth in claim 1,
wherein each of the surface acoustic wave (SAW) devices comprises a piezoelectric film formed on the main surface of the silicon sample and a comb-shaped electrode formed on the piezoelectric film.

5. The evaluating method as set forth in claim 4,
wherein the piezoelectric film is made of zinc oxide (ZnO), aluminum nitride or polyvinylidene fluoride and the comb-shaped electrode is made of aluminum (Al) or copper (Cu).

6. The evaluating method as set forth in claim 1,
wherein the silicon sample is attached to a silver plate or a silver film.

7. The evaluating method as set forth in claim 1,
wherein the concentration “N” of atomic vacancy is defined by obtaining a low temperature softening ΔCₛ/Cₛ of the constant Cs of the surface layer of the silicon sample and considering that the softening of the elastic constant Cₛ of the surface acoustic wave (SAW) corresponds to the concentration of atomic vacancy of N=(1.6±0.2)×10¹²/cm³ as the use of unit of ΔCₛ/Cₛ=10⁻⁴.

8. The evaluating method as set forth in claim 1,
wherein the concentration “N” of atomic vacancy is defined by obtaining a low temperature softening ΔCₛ/Cₛ dependent on a change of the intensity of the magnetic field within a range of 0 to 10 teslas when the elastic constant Cₛ of the surface layer of the silicon sample is calculated at a temperature within a range 10 mK to 50 mK and considering that the softening of the elastic constant Cₛ of the surface acoustic wave (SAW) corresponds to the concentration of atomic vacancy of N=(1.6±0.2)×10¹²/cm³ as the use of unit of ΔCₛ/Cₛ=10⁻⁴.

9. An apparatus for evaluating atomic vacancy in a surface layer of a silicon wafer, comprising:
a silicon sample provided with an ultrasonic wave generating portion and an ultrasonic wave receiving portion;
a magnetic field generator for applying an external magnetic field to the silicon sample;
a refrigerator for cooling the silicon sample; and
a measuring means for detecting a difference in phase between an ultrasonic wave pulse injected from the ultrasonic wave generating portion and an ultrasonic wave pulse propagated in the silicon sample and received at the ultrasonic wave receiving portion;
wherein the ultrasonic generating portion and the ultrasonic receiving portion are respective comb-shaped electrodes formed on corresponding piezoelectric films and are formed on the same main surface of the silicon sample.

10. The evaluating apparatus as set forth in claim 9,
wherein the piezoelectric film is made of zinc oxide, aluminum nitride or polyvinylidene fluoride and the comb-shaped electrode is made of aluminum (Al) or copper (Cu).

11. The evaluating apparatus as set forth in claim 9,
wherein the silicon sample is attached to a silver plate or a silver film.

12. A silicon wafer, comprising a concentration of atomic vacancy in a surface layer thereof which is evaluated by an evaluating method as set forth in claim 1 and distinguished from a concentration of atomic vacancy in a bulk thereof.

13. A method for manufacturing a silicon wafer, comprising steps of:
forming a pair of surface acoustic wave (SAW) devices which are arranged opposite to one another on the same main surface of a silicon sample;
generating an ultrasonic wave pulse from one of the surface acoustic wave (SAW) devices and propagating the ultrasonic wave pulse in a surface layer of the silicon sample while the silicon sample is cooled under a condition of an application of magnetic field, and receiving the propagated ultrasonic wave pulse at the other of the surface acoustic wave (SAW) devices, thereby measuring a difference in phase between the injected ultrasonic wave pulse and the propagated ultrasonic wave pulse; and
calculating an elastic constant Cₛ of the surface layer of the silicon sample based on the difference in phase and evaluating a concentration “N” of atomic vacancy of the surface layer of the silicon sample based on a change of the elastic constant Cₛ with a temperature or a change of the elastic constant Cₛ with an intensity of the magnetic field.

14. A silicon wafer manufactured by a manufacturing method as set forth in claim 13.
